(19) United States
(12) Patent Application Publication
(10) Pub. No.: US 2025/0241187 A1
(43) Pub. Date: Jul. 24, 2025

(54) DISPLAY DEVICE, METHOD OF FABRICATING THE SAME, AND ELECTRONIC DEVICE INCLUDING THE SAME

(71) Applicant: Samsung Display Co., LTD., Yongin-si (KR)

(72) Inventors: Rang Kyun MOK, Yongin-si (KR); Young Sang HA, Yongin-si (KR); Yong Seok KIM, Yongin-si (KR); Saet Byeol SHIN, Yongin-si (KR); Tae Ho LEE, Yongin-si (KR)

(73) Assignee: Samsung Display Co., LTD., Yongin-si (KR)

(21) Appl. No.: 18/966,934

(22) Filed: Dec. 3, 2024

(30) Foreign Application Priority Data
Jan. 19, 2024 (KR) 10-2024-0009060

(51) Int. Cl. H10K 59/80

(52) U.S. Cl. CPC H10K 59/8792

(57) ABSTRACT

A display device may include: a display panel that outputs light for displaying an image; a first electrode layer disposed on the display panel; a light control layer including a light blocking component that blocks at least some of the light; and a second electrode layer disposed on the light control layer. The light blocking component may include at least one light blocking unit that is controlled in response to voltages applied to the first electrode layer and the second electrode layer. The light blocking unit may be substantially uniformly disposed in the light blocking component in a first mode, and may be disposed adjacent to any one of the first electrode layer and the second electrode layer in a second mode different from the first mode.

### CROSS-REFERENCE TO RELATED APPLICATION(S)

This application claims priority to and benefits of Korean patent application number 10-2024-0009060 under 35 U.S.C. § 119, filed on Jan. 19, 2024, the entire contents of which are incorporated herein by reference.

### BACKGROUND

### 1. Field of Invention

Various embodiments relate to a display device, and more particularly, to a display device, a method of fabricating the display device, and an electronic device including the display device.

### 2. Description of Related Art

Display devices may include a display panel that outputs light so as to display an image, and a window disposed on the display panel. Light outputted from the display panel may pass through a function panel and a window and be emitted in a direction toward a front surface of a display device.

With the development of technology, vehicles have evolved beyond simple means of transportation include various display devices. The display devices may provide various information including not only real-time traffic information but also the current statuses of vehicles.

However, light emitted from the display device may be directly visible to a driver, or may be visible to the driver after being reflected by a windshield of the vehicle. For example, at least some of the light emitted from the display device may obstruct the driver's field of vision. To prevent the aforementioned problem, a light control layer capable of controlling the emission angle of light emitted from the display device may be disposed on the display panel and the window.

The information disclosed in this background section is only for enhancement of understanding of the background of the described technology and therefore it may contain information that does not form the prior art that is already known to a person of ordinary skill in the art.

### SUMMARY

Various embodiments are directed to a display device that outputs an image using a light control layer such that unintended light may be prevented from being visible to a user of the display device in a first mode, and the user of the display device may view (or observe) the display device with a relatively wide viewing angle in a second mode.

Various embodiments are directed to a method of fabricating the display device capable of facilitating a process of fabricating the display device including a light control layer.

However, embodiments are not limited to those set forth herein. The above and other embodiments will become more apparent to one of ordinary skill in the art to which the disclosure pertains by referencing the detailed description of the disclosure given below.

An embodiment may provide a display device, including: a display panel that outputs light for displaying an image; a first electrode layer disposed on the display panel; a light control layer including a light blocking component that blocks at least some of the light; and a second electrode layer disposed on the light control layer.

The light blocking component may include at least one light blocking unit that is controlled in response to voltages applied to the first electrode layer and the second electrode layer. The light blocking unit may be substantially uniformly disposed in the light blocking component in a first mode, and may be disposed adjacent to any one of the first electrode layer and the second electrode layer in a second mode different from the first mode.

In the first mode, the first electrode layer and the second electrode layer may be electrically floated. In the second mode, voltages of different magnitudes may be applied to the first electrode layer and the second electrode layer.

Voltages having an identical magnitude may be applied to the first electrode layer and the second electrode layer in the first mode. Voltages of different magnitudes may be applied to the first electrode layer and the second electrode layer in the second mode.

The light blocking component may have a trapezoidal shape or an inverted trapezoidal shape.

A distance between a first side and a second side of the light blocking component that extend parallel to each other may range from about 30 μm to about 100 μm.

A length of the second side may be about 4 μm or more, and the length of the second side may be less than a length of the first side.

The light blocking component may include: a first light blocking component; and a second light blocking component disposed to be shifted from the first light blocking component by a distance in a range of about 30 μm or more.

In the second mode, the light blocking component may include a first area in which the light blocking unit is disposed, and a second area in which the light blocking unit is not disposed.

As a vertical length of the first area decreases, a proportion of light passing through the light control layer among the light outputted from the display panel may increase.

A refractive index of the light control layer may be substantially identical to a refractive index of the second area.

An embodiment may provide an electronic device including: a processor that provides input image data to a display device; and the display device that displays an image based on the input image data. The display device may include: a display panel that outputs light for displaying an image; a first electrode layer disposed on the display panel; a light control layer including a light blocking component that blocks at least some of the light; and a second electrode layer disposed on the light control layer. The light blocking component may include at least one light blocking unit that is controlled in response to voltages applied to the first electrode layer and the second electrode layer. The light blocking unit may be substantially uniformly disposed in the light blocking component in a first mode, and may be disposed adjacent to any one of the first electrode layer and the second electrode layer in a second mode different from the first mode.

An embodiment may provide a method of fabricating a display device, including: forming a first electrode layer on a display panel; forming a light transmitting layer on the first electrode layer; forming an opening by etching the light transmitting layer in a direction toward the first electrode layer; forming a light control layer by disposing a light blocking component including at least one light blocking unit in the opening; forming an organic layer on the light control layer; and forming a second electrode layer on the organic layer. The light blocking unit may be controlled according to magnitudes of voltages applied to the first electrode layer and the second electrode layer.

The forming of the organic layer may include curing the organic layer by heat. The organic layer may include an acrylic material.

The forming of the organic layer may include curing the organic layer by an ultraviolet ray. The organic layer may include a silicon material.

The method may further include: etching at least a portion of the second electrode layer; etching at least a portion of the organic layer; and etching at least a portion of the first electrode layer.

The second electrode layer may include an upper electrode and an insulating layer disposed to cover at least a portion of the upper electrode. The insulating layer may include an etching portion overlapping an end portion of the upper electrode. The etching of at least the portion of the first electrode layer may include etching the etching portion.

According to the magnitudes of the voltages applied to the first electrode layer and the second electrode layer, the light blocking unit may be substantially uniformly disposed in the light blocking component in a first mode, and may be disposed adjacent to any one of the first electrode layer and the second electrode layer in a second mode different from the first mode.

In the first mode, the first electrode layer and the second electrode layer may be electrically floated. In the second mode, voltages of different magnitudes may be applied to the first electrode layer and the second electrode layer.

In the first mode, voltages having an identical magnitude may be applied to the first electrode layer and the second electrode layer. In the second mode, voltages of different magnitudes may be applied to the first electrode layer and the second electrode layer.

The light blocking component may have a trapezoidal shape or an inverted trapezoidal shape. A distance between a first side and a second side of the light blocking component that extend parallel to each other may range from about 30 μm to about 100 μm.

### BRIEF DESCRIPTION OF THE DRAWINGS

FIG. 1 is a schematic diagram illustrating a display device in accordance with embodiments.

FIG. 2 is a schematic sectional view illustrating an embodiment of the display device taken along line I-I′ of FIG. 1.

FIG. 3 is a schematic sectional view illustrating an area A of the display device of FIG. 2.

FIG. 4 is a schematic sectional view illustrating the area A of the display device of FIG. 2 in case that the display device is driven in a first mode.

FIG. 5 is a schematic sectional view illustrating the area A of the display device of FIG. 2 in case that the display device is driven in a second mode.

FIG. 6 is a schematic sectional view illustrating an area B of the display device of FIG. 2 in case that the display device is driven in the second mode.

FIG. 7A is a diagram depicting light transmittance as a function of a viewing angle for each first height of a first area in FIG. 6.

FIG. 7B is a diagram depicting light transmittance as a function of a viewing angle for each light transmittance of a second area in FIG. 6.

FIG. 7C is a diagram depicting light transmittance as a function of the viewing angle according to a difference between the refractive index of the second area and the refractive index of the light transmitting layer LTL in FIG. 6.

FIG. 7D is a diagram showing a lookup table including simulation values for respective viewing angles of the display device in accordance with an embodiment.

FIG. 7E is a diagram showing a measurement table including measurement values for respective viewing angles of the display device in accordance with an embodiment.

FIG. 7F is a diagram showing a graph comparing the measurement value and the simulation value according to the viewing angle of the light outputted from the display device.

FIG. 8 is a flowchart illustrating a method of fabricating the display device in accordance with an embodiment.

FIGS. 9 to 17 are schematic sectional views illustrating a method of fabricating the display device in accordance with an embodiment.

FIG. 18 is a block diagram illustrating an electronic device in accordance with embodiments.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

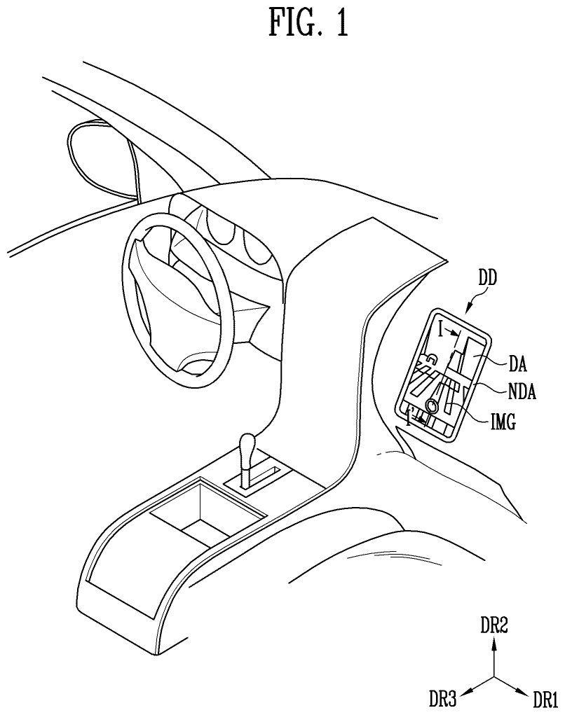

FIG. 1 is a schematic diagram illustrating a display device DD in accordance with embodiments.

The display device DD illustrated in FIG. 1 may be a center information display (CID) for vehicles. The display device DD may be a device that is activated in response to an electrical signal. The display device DD may encompass various embodiments. For example, the display device DD may be applied to transportation vehicles such as an automobile, a bicycle, a motorcycle, a ship, and an airplane. Furthermore, the display device DD may be applied not only to large electronic devices such as a television, a monitor, and an electronic display board, but also to small and medium electronic devices such as a tablet PC, a navigation device, a game console, and a smart watch. Furthermore, the display device DD may also be applied to a wearable electronic device such as a head-mount display (HMD). The aforementioned examples are for illustrative purposes, and unless departing from the concepts of the disclosure, the display device DD may also be implemented as other display devices.

The display device DD may be an organic light emitting display device (OLED), but embodiments are not limited thereto. For example, the display device DD may be implemented as a liquid crystal display device (LCD) according to an embodiment. Hereinafter, for the convenience of explanation, the display device DD is described as being an organic light emitting display device.

A display area DA and a non-display area NDA may be defined in the display device DD. The display area DA may be an area in which an image IMG is displayed. In FIG. 1, traffic conditions are illustrated as an example of the image IMG. The non-display area NDA may be an area in which the image IM is not displayed.

The display device DD may be disposed in parallel to a surface inclined in a direction opposite to the third direction DR3 with respect to a plane formed in a first direction DR1 and a second direction DR2. Accordingly, at least some of the light forming the image IM outputted from the display device DD may travel (or transmit) straight and be irradiated onto a windshield of a vehicle.

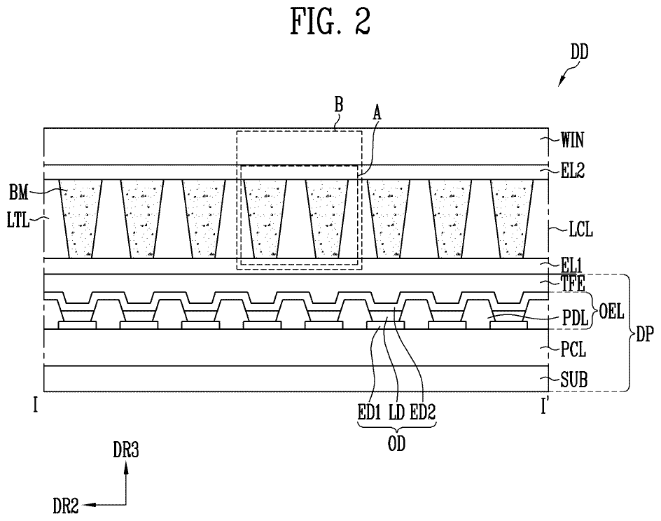

FIG. 2 is a schematic sectional view illustrating an embodiment of the display device DD taken along line I-I′ of FIG. 1.

Referring to FIG. 2, the display device DD may include a display panel DP, a first electrode layer EL1, a light control layer LCL, a second electrode layer EL2, and a window WIN.

The display panel DP may include a substrate SUB, a circuit layer PCL, a display element layer OEL, and an encapsulation layer TFE.

The substrate SUB may be formed of a polymer substrate, a plastic substrate, a glass substrate, a quartz substrate, or the like. The substrate SUB may be formed of a transparent insulating substrate. The substrate SUB may be rigid. The substrate SUB may be flexible.

The circuit layer PCL may be disposed on the substrate SUB. The substrate SUB and/or the circuit layer PCL may include insulating layers, and conductive patterns disposed between the insulating layers. The conductive patterns of the circuit layer PCL may function as at least some of the circuit elements, lines, or the like. The conductive patterns may include copper, but embodiments are not limited thereto.

The display element layer OEL may include one or more light emitting elements OD. The light emitting elements OD may include a first light emitting electrode ED1, a functional layer LD, a second light emitting electrode ED2 that are sequentially stacked. The functional layer LD may include a hole transport layer, an emission layer, and an electron transport layer that are sequentially stacked. One or more light emitting elements OD may emit light in respective different wavelength bands.

For example, any one of the one or more light emitting elements OD may emit light having a wavelength in a range of about 630 nm to about 750 nm (nanometers). Another one of the one or more light emitting elements OD may emit light having a wavelength in a range of about 495 nm to about 570 nm. Another one of the one or more light emitting elements OD may emit light having a wavelength in a range of about 450 nm to about 495 nm.

The display element layer OEL may include a pixel defining layer PDL. In the display element layer OEL, the light emitting elements OD may be separated from each other by the pixel defining layer PDL.

In embodiments, the pixel defining layer PDL may include an inorganic material. For example, the pixel defining layer PDL may include inorganic layers stacked on top of one another. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited to the aforementioned examples.

The encapsulation layer TFE may be disposed on the display element layer OEL and encapsulate the display element layer OEL. The encapsulation layer TFE may protect the display element layer OEL from water and/or oxygen, and may protect the display element layer OEL from foreign substances such as dust particles. The encapsulation layer TFE may include at least one inorganic layer or at least one organic layer. The encapsulation layer TFE may have a structure in which organic layers and inorganic layers are alternately and repeatedly stacked. For example, the encapsulation layer TFE may have a structure in which an inorganic layer, an organic layer, and an inorganic layer are sequentially stacked.

In an embodiment, the display device DD may further include an input sensing layer disposed on the display panel DP. The input sensing layer may sense an input applied from an external device. The input applied from the external device may be provided in various forms. For example, external inputs may include various types of external inputs provided using a part of the body of a user, a stylus pen, light, heat, pressure, etc.

The first electrode layer EL1 may be disposed on the display panel DP. The first electrode layer EL1 may be formed of a transparent conductive material. For example, the first electrode layer EL1 may include indium tin oxide (ITO), or indium zinc oxide (IZO). However, embodiments are not limited to the aforementioned example, and the first electrode layer EL1 may include at least one of a transparent conductive materials such as zinc oxide (ZnOₓ), indium gallium zinc oxide (IGZO), and indium tin zinc oxide (ITZO). In embodiments, the zinc oxide (ZnOₓ) may be zinc oxide (ZnO) and/or zinc peroxide (ZnO₂).

The light control layer LCL may be disposed on the first electrode layer EL1. The light control layer LCL may include a light transmitting layer LTL. The light transmitting layer LTL may be formed of a transparent organic material. Accordingly, the light transmitting layer LTL may transmit at least some of the light that is incident on the light control layer LCL.

The light control layer LCL may include a light blocking component BM. For example, the light control layer LCL may include light blocking components BM spaced apart from each other at regular intervals (or distances) in a direction (e.g., the second direction DR2).

The light blocking components BM may block at least some of the light that is incident on the light control layer LCL. For example, the light blocking components BM may absorb some of the light that is incident on the light control layer LCL, thus preventing the some of the light from being visible to the eyes of the user of the display device DD.

The second electrode layer EL2 may be disposed on the light control layer LCL. The second electrode layer EL2 may be supplied with a certain voltage from an external device. The second electrode layer EL2 may be formed of a transparent conductive material. For example, the second electrode layer EL2 may include indium tin oxide (ITO), or indium zinc oxide (IZO). However, embodiments are not limited to the aforementioned example, and the second electrode layer EL2 may include at least one of a transparent conductive materials such as zinc oxide (ZnOₓ), indium gallium zinc oxide (IGZO), and indium tin zinc oxide (ITZO).

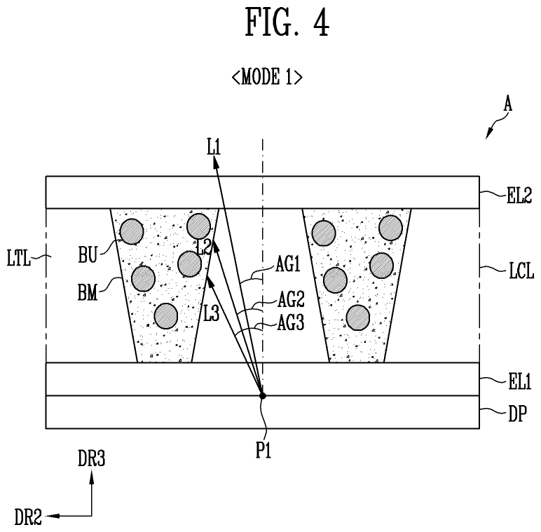

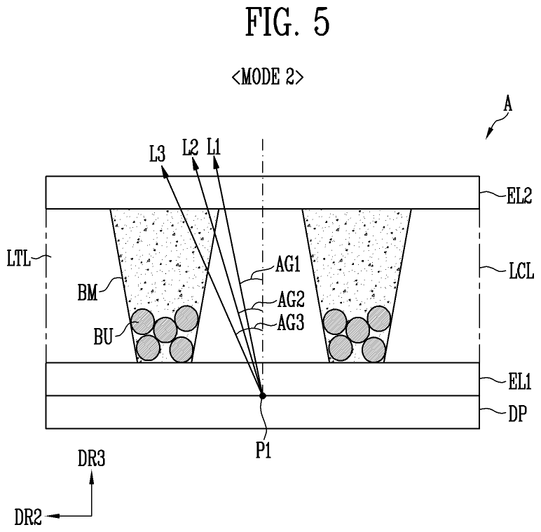

The first electrode layer EL1 and the second electrode layer EL2 may receive a voltage applied from an external device. The first electrode layer EL1 and the second electrode layer EL2 may form an electric field in response to the voltage applied from the external device. Thus, the light control layer LCL may control the light that is incident on the light control layer LCL. Further details will be described later herein with reference to FIGS. 4 and 5.

The window WIN may be disposed on the second electrode layer EL2. For example, the window WIN may be disposed on the second electrode layer EL2, thereby protecting an upper surface of the display device DD.

The window WIN may include an optically transparent insulating material. For example, the window WIN may include glass or plastic. Furthermore, the window WIN may be formed of a multilayer structure or a single-layer structure. For example, the window WIN may include one or more plastic films bonded to each other by an adhesive, or may include a glass substrate and a plastic film bonded to each other by an adhesive.

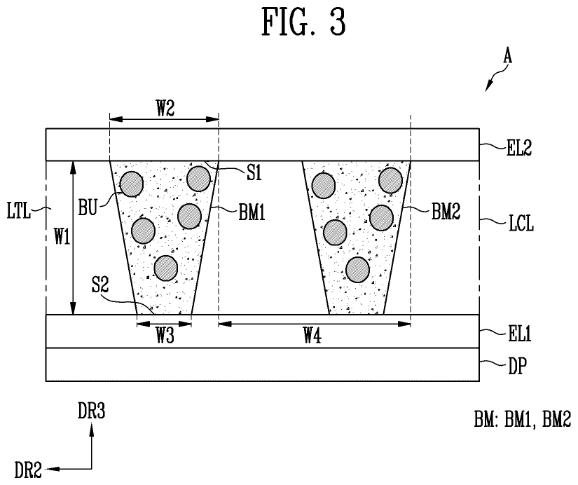

FIG. 3 is a schematic sectional view illustrating an area A of the display device DD of FIG. 2. FIG. 4 is a schematic sectional view illustrating the area A of the display device DD of FIG. 2 in case that the display device is driven in a first mode MODE 1. FIG. 5 is a schematic sectional view illustrating the area A of the display device DD of FIG. 2 in case that the display device is driven in a second mode MODE 2.

Referring to FIG. 3, each of the light blocking components BM may have an inverted trapezoidal cross-sectional shape. However, embodiments are not limited thereto. For example, each of the light blocking components BM may have a trapezoidal shape.

Referring to FIGS. 3 to 5, the display panel DP may include a first portion P1 formed to output at least one of light beams for displaying the image IMG (refer to FIG. 1). For example, the first portion P1 may include one or more light emitting elements. The first portion P1 may be positioned without overlapping the light blocking component BM in the third direction DR3. For example, the display panel DP may output first, second, and third light beams L1, L2, and L3 traveling (or transmitting) straight from the first portion Pl at different angles with respect to the third direction DR3. The first light beam L1 may travel (or transmit) straight from the first portion P1 at a first angle AG1 with respect to the third direction DR3. The second light beam L2 may travel (or transmit) straight from the first portion P1 at a second angle AG2 with respect to the third direction DR3. The third light beam L3 may travel (or transmit) straight from the first portion P1 at a third angle AG3 with respect to the third direction DR3.

Referring to FIGS. 3 and 4, the light blocking component BM may include a first side S1 and a second side S2 that extend parallel to each other. A height of the light blocking component BM may be a first length W1. For example, a distance between the first side S1 and the second side S2 of the light blocking component BM may correspond to the first length W1. In an embodiment, the first length W1 may range from about 30 μm (micrometers) to about 100 μm, but embodiments are not limited thereto. For example, according to a comparative example, the first length W1 may be less than about 30 μm. For example, in a first mode MODE 1, the light beams L1 to L3 outputted from the first portion P1 may not be blocked at all by the light blocking component BM. According to another comparative example, the first length W1 may be about 100 μm or more. For example, in the first mode MODE 1, the light beams L1 to L3 outputted from the first portion P1 may be completely blocked by the light blocking component BM. For example, in accordance with an embodiment, in the first mode MODE 1, the light blocking component BM may block only intended light beams (e.g., the second light beam L2 and the third light beam L3) among the light beams L1 to L3 outputted from the first portion P1.

A length of the first side S1 of the light blocking component BM may be a second length W2. A length of the second side S2 of the light blocking component BM may be a third length W3. In an embodiment, each of the second length W2 and the third length W3 may be about 4 μm or more. For example, the second length W2 may be about 12 μm, and the third length W3 may be about 6 μm.

The light blocking components BM may be spaced apart from each other at regular intervals (or distances) in a direction (e.g., second direction DR2). For example, the light blocking components BM may include a first light blocking component BM1 and a second light blocking component BM2 shifted by a certain distance (e.g., a fourth length W4) from the first light blocking component BM1. For example, a right end portion of the first light blocking component BM1 and a right end portion of the second light blocking component BM2 may be spaced apart from each other by the fourth length W4 in the second direction DR2. In an embodiment, the fourth length W4 may be about 30 μm or more, but embodiments are not limited thereto. For example, in accordance with an embodiment, the fourth length W4 may be about 35 μm. For example, according to a comparative example, the fourth length W4 may be about 17.5 μm. In accordance with an embodiment, in the first mode MODE 1, a proportion of light passing through the light control layer LCL among the light beams L1 to L3 outputted from the first portion P1 may increase by two times compared to that of the comparative example. Thus, in the first mode MODE 1, only an intended light beam (e.g., the first light beam L1) among the light beams L1 to L3 outputted from the first portion P1 may pass through the light control layer LCL.

Referring to FIGS. 3 to 5, the light blocking component BM may include at least one or more light blocking units BU. The light blocking units BU may absorb some of the light that is incident on the light blocking component BM. Thus, the light blocking units BU may block at least some of the light that is incident on the light blocking component BM. For example, at least some of the light that is incident on the light blocking component BM may be irradiated onto the light blocking unit BU. The light blocking unit BU may absorb light irradiated onto the light blocking unit BU, and the corresponding light may not be outputted to the upper surface of the display device (DD, refer to FIG. 2).

In an embodiment, the light blocking unit BU may include carbon black. However, the material of the light blocking unit BU is not limited to the aforementioned example, so long as the light blocking unit BU absorbs light irradiated thereonto.

The light blocking unit BU may be controlled in response to voltages applied to the first electrode layer EL1 and the second electrode layer EL2. For example, the light blocking unit BU may have an electrical polarity and be controlled by an electric field formed between the first electrode layer EL1 and the second electrode layer EL2.

Referring to FIG. 4, in the first mode MODE 1, no voltage may be applied to the first electrode layer EL1 and the second electrode layer EL2 or the first electrode layer EL1 and the second electrode layer EL2 may be electrically floated. In an embodiment, in the first mode MODE 1, voltages having the same magnitude may be applied to the first electrode layer EL1 and the second electrode layer EL2. For example, electrical power may not be applied to the light blocking unit BU. Thus, the light blocking units BU may be substantially uniformly disposed in the light blocking component BM.

Referring to FIG. 5, in the second mode MODE 2, voltages of different magnitudes may be applied to the first electrode layer EL1 and the second electrode layer EL2. Thus, a certain magnitude of electrical power may be applied to the light blocking unit BU. For example, the light blocking unit BU may have a negative charge. For example, in the second mode MODE 2, a voltage of 1V may be applied to the first electrode layer EL1, and a voltage of 11V may be applied to the second electrode layer EL2. Thus, an electric field may be formed between the first electrode layer EL1 and the second electrode layer EL2. In the aforementioned embodiment, electrical power may be applied to the light blocking unit BU in a direction opposite to the third direction DR3, and the light blocking unit BU may move in a direction toward the first electrode layer EL1. For example, the magnitude of voltage applied to each of the first electrode layer EL1 and the second electrode layer EL2 is an example and is not limited thereto. A direction in which the light blocking unit BU moves in the electric field may be controlled according to the relative magnitude of the voltage applied to each of the first electrode layer EL1 and the second electrode layer EL2. A speed at which the light blocking unit BU moves in the electric field may be controlled according to the magnitude of a voltage difference between the first electrode layer EL1 and the second electrode layer EL2.

Referring to FIG. 4, in the first mode MODE 1, the light blocking units BU may be substantially uniformly disposed (or distributed) in the light blocking component BM. The first light beam L1 may travel (or transmit) straight without being blocked by the light control layer LCL. For example, the first light beam L1 may pass through the light control layer LCL because the first light beam L1 is not irradiated onto the light blocking units BU disposed in the light blocking component BM. For example, the second light beam L2 and the third light beam L3 may not pass through the light control layer LCL. For example, the second light beam L2 and the third light beam L3 may be absorbed by the light blocking units BU disposed in the light blocking component BM rather than passing through the light control layer LCL. Thus, in the first mode MODE 1, a threshold angle of a light beam that can pass through the light control layer LCL among the light beams L1 to L3 outputted from the first portion P1 may be substantially equal to an absolute value of the first angle AG1. Thus, the display device DD may have a relatively narrow viewing angle in the first mode MODE 1.

Referring to FIG. 5, in the second mode MODE 2, the light blocking units BU may be disposed adjacent to the first electrode layer EL1 in response to the voltages applied to the first electrode layer EL1 and the second electrode layer EL2. For example, the light blocking units BU may be moved to an end portion (or lower portion) of the light blocking component BM that is adjacent to the first electrode layer EL1 by electrical power applied in a direction opposite to the third direction DR3. Thus, the light blocking units BU may not be disposed on a remaining end portion of the light blocking component BM that is adjacent to the second electrode layer EL2. The first light beam L1 may travel (or transmit) straight without being blocked by the light control layer LCL. For example, the first light beam L1 may pass through the light control layer LCL because the first light beam L1 is not irradiated onto the light blocking unit BU disposed in the light blocking component BM. Furthermore, the second light beam L2 and the third light beam L3 may travel (or transmit) straight rather than being blocked by the light control layer LCL. For example, the second light beam L2 and the third light beam L3 may not collide with (or may not be blocked by) the light blocking units BU. Accordingly, the second light beam L2 and the third light beam L3 may travel (or transmit) straight through the light blocking units BU. Thus, in the second mode MODE 2, a threshold angle of a light beam that can pass through the light control layer LCL among the light beams L1 to L3 outputted from the first portion P1 may be greater than an absolute value of the third angle AG3.

In an embodiment, an emission angle of light outputted from the display device (DD, refer to FIG. 2) may be controlled based on the magnitudes of voltages applied to the first electrode layer EL1 and the second electrode layer EL2. For example, in the first mode MODE 1, no voltage may be applied to the first electrode layer EL1 and the second electrode layer EL2 (or the first electrode layer EL1 and the second electrode layer EL2 may be electrically floated), and the light blocking units BU may be substantially uniformly disposed in the light blocking component BM. Thus, the emission angle of light outputted from the display device DD may be relatively reduced, and unintended light may be prevented from being visible to the user of the display device DD. For example, in the second mode MODE 2, voltages of different magnitudes may be applied to the first electrode layer EL1 and the second electrode layer EL2, and the light blocking units BU may be disposed to be biased (or shifted) to a portion adjacent to the first electrode layer EL1. Accordingly, the emission angle of the light outputted from the display device DD may be relatively increased, so that the user of the display device DD may view (or observe) an image expressed from the display device DD with a relatively wide viewing angle.

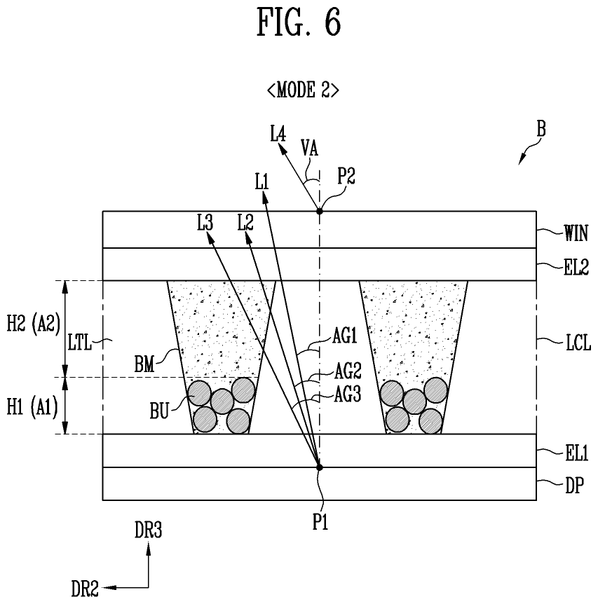

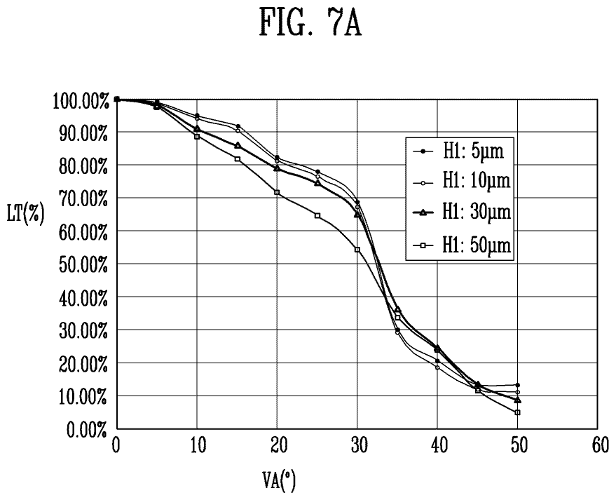

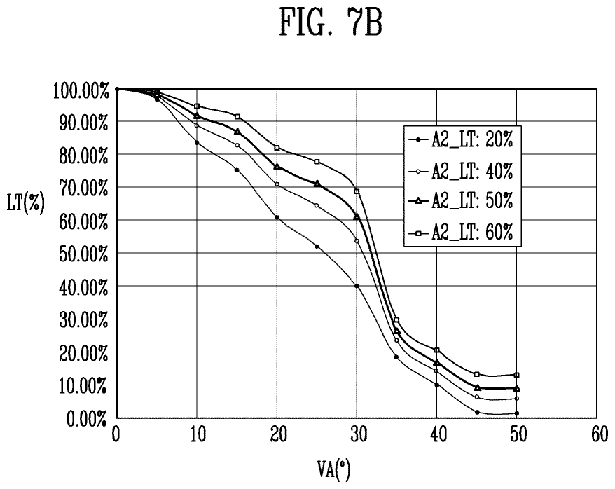

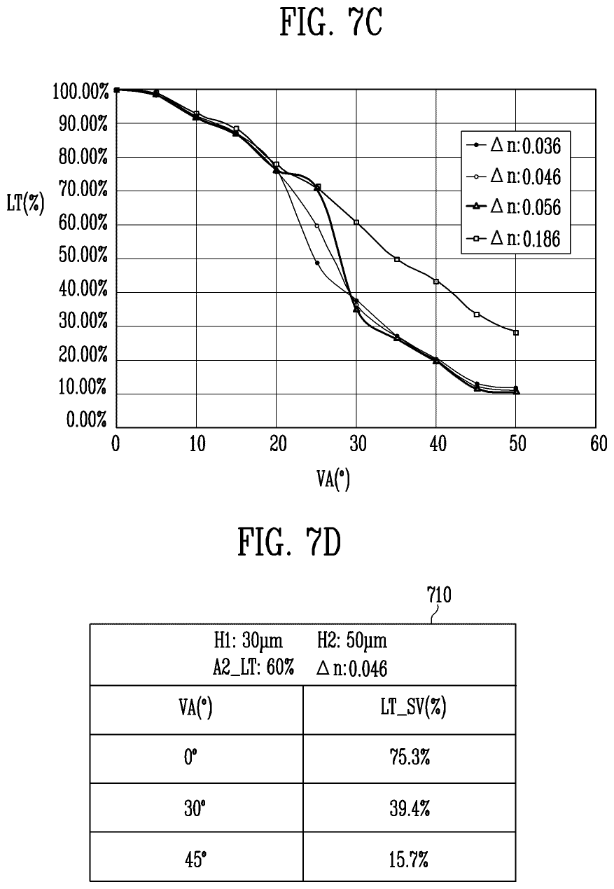

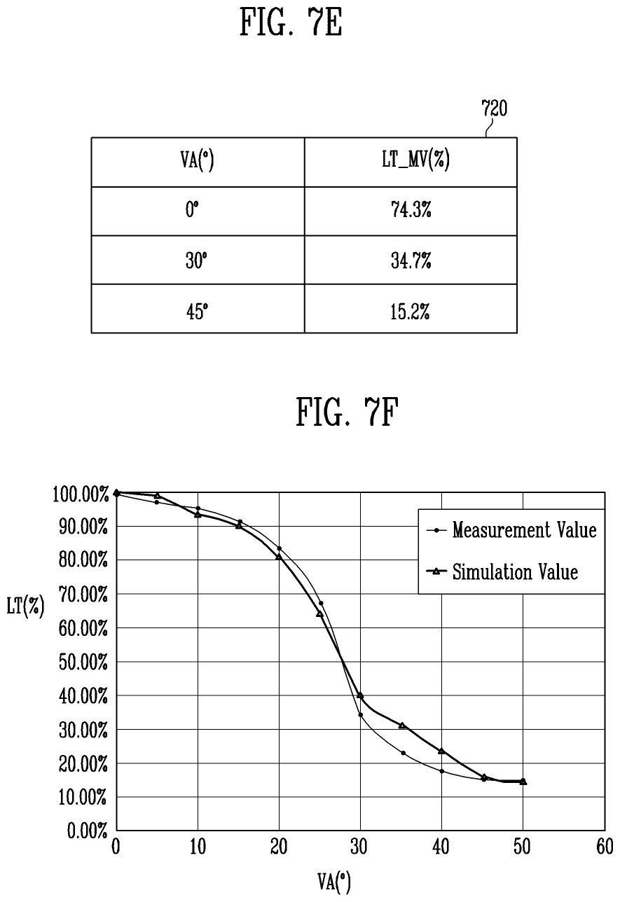

FIG. 6 is a schematic sectional view illustrating an area B of the display device DD of FIG. 2 in case that the display device is driven in the second mode MODE 2. FIG. 7A is a diagram depicting light transmittance as a function of the viewing angle for each first height of a first area A1 in FIG. 6. FIG. 7B is a diagram depicting light transmittance as a function of a viewing angle for each light transmittance of a second area A2 in FIG. 6. FIG. 7C is a diagram depicting light transmittance as a function of the viewing angle according to a difference between the refractive index of the second area A2 and the refractive index of the light transmitting layer LTL in FIG. 6. FIG. 7D is a diagram showing a lookup table including simulation values for respective viewing angles of the display device DD in accordance with an embodiment. FIG. 7E is a diagram showing a measurement table including measurement values for respective viewing angles of the display device DD in accordance with an embodiment. FIG. 7F is a diagram showing a graph comparing the measurement value and the simulation value according to the viewing angle of the light outputted from the display device DD.

Referring to FIG. 6, in the case where the display device (DD, refer to FIG. 2) in accordance with an embodiment is driven in the second mode MODE 2, the light blocking component BM may include a first area A1 and a second area A2 different from the first area A1. For example, the light blocking component BM may include the first area A1 where the light blocking units BU are disposed, and the second area A2 where the light blocking units BU are not disposed. For example, a height of the first area A1 in the third direction DR3 may be a first height H1, and a height of the second area A2 in the third direction DR3 may be a second height H2.

Referring to FIG. 6, at least some of the light beams outputted from the display panel DP and passing through the light control layer LCL may pass through the second portion P2. For example, a fourth light beam L4 may be at least some of the light beams passing through the light control layer LCL and outputted to the second portion P2. The second portion P2 may be any one portion of an upper surface of the window WIN.

Referring to FIGS. 6 and 7A to 7C, the fourth light beam L4 may be outputted to be inclined at a certain angle in the second direction DR2 based on the second portion P2. For example, a certain angle at which the fourth light beam L4 passes through the second portion P2 based on the third direction DR3 may correspond to the viewing angle VA of the user of the display device (DD, refer to FIG. 2). For example, the user of the display device DD may perceive the fourth light beam L4 from a viewpoint inclined by the viewing angle VA based on the second portion P2.

Referring to FIGS. 6 and 7A, the sum of the first height H1 and the second height H2 may be about 80 μm. For example, the first height H1 may be about 5 μm, and the second height H2 may be about 75 μm. However, embodiments are not limited thereto. For example, the first height H1 may be about 10 μm, and the second height H2 may be about 70 μm. In another example, the first height H1 may be about 30 μm, and the second height H2 may be about 50 μm. In still another example, the first height H1 may be about 50 μm, and the second height H2 may be about 30 μm.

Referring to FIGS. 6 and 7A, as the first height H1 of the first area A1 where the light blocking units BU are disposed decreases, the light transmittance LT as a function of the viewing angle VA for the light outputted from the display device (DD, refer to FIG. 2) may increase. For example, the light transmittance LT as a function of the viewing angle VA for the light outputted from the display device DD in the case where the first height H1 of the first area A1 is about 5 μm may be greater than the light transmittance LT as a function of the viewing angle VA for the light outputted from the display device DD in the case where the first height H1 of the first area A1 is about 50 μm. For example, the light transmittance LT may be a proportion of light passing through the light control layer LCL among light beams outputted from the display panel DP according to the viewing angle VA. For example, the light transmittance LT may vary according to the viewing angle VA. For example, according to a position relationship between the display device DD and the user of the display device DD, the viewing angle VA may vary, and the light transmittance LT may also vary.

Referring to FIGS. 6 and 7B, a light transmittance A2_LT of the second area A2 may be about 20%. However, embodiments are not limited thereto. For example, in an embodiment, the light transmittance A2_LT of the second area A2 may be about 40%. Furthermore, the light transmittance A2_LT of the second area A2 may be about 50%. In another embodiment, the light transmittance A2_LT of the second area A2 may be about 60%. For example, the light transmittance A2_LT of the second area A2 may be a proportion of light passing through the second area A2 among light beams that are outputted from the display panel DP and are incident on the second area A2. For example, in the case where the light transmittance A2_LT of the second area A2 is about 20%, only about 20% of light among the second light beam L2 and the third light beam L3 that are incident on the second area A2 may pass through the second area A2.

Referring to FIGS. 6 and 7B, as the light transmittance A2_LT of the second area A2 increases, the light transmittance LT as a function of the viewing angle VA for the light outputted from the display device (DD, refer to FIG. 2) may increase. For example, the light transmittance LT as a function of the viewing angle VA for the light outputted from the display device DD in the case where the light transmittance A2_LT of the second area A2 is about 60% may be greater than the light transmittance LT as a function of the viewing angle VA for the light outputted from the display device DD in the case where the light transmittance A2_LT of the second area A2 is about 20%.

Referring to FIGS. 6 and 7C, an absolute value Δn of the difference between a refractive index of the second area A2 and a refractive index of the light transmitting layer LTL may be about 0.036. However, embodiments are not limited thereto. For example, the absolute value Δn of the difference between the refractive index of the second area A2 and the refractive index of the light transmitting layer LTL may be about 0.046. Furthermore, the absolute value Δn of the difference between the refractive index of the second area A2 and the refractive index of the light transmitting layer LTL may be about 0.056. In another embodiment, the absolute value Δn of the difference between the refractive index of the second area A2 and the refractive index of the light transmitting layer LTL may be about 0.186.

Referring to FIGS. 6 and 7C, as the absolute value Δn of the difference between the refractive index of the second area A2 and the refractive index of the light transmitting layer LTL increases, the light transmittance LT as a function of the viewing angle VA for the light outputted from the display device (DD, refer to FIG. 2) may increase. For example, the light transmittance LT as a function of the viewing angle VA for the light outputted from the display device DD in the case where the absolute value Δn of the difference between the refractive index of the second area A2 and the refractive index of the light transmitting layer LTL is about 0.186 may be higher than the light transmittance LT as a function of the viewing angle VA for the light outputted from the display device DD in the case where the absolute value Δn of the difference between the refractive index of the second area A2 and the refractive index of the light transmitting layer LTL is about 0.056.

Referring to FIGS. 7D to 7F, an electronic device may determine parameters of the light control layer LCL based on the light transmittance LT as a function of the viewing angle VA for the light outputted from the display device DD. For example, the parameters to be determined by the electronic device may include at least one of the first height H1 of the first area A1, the second height H2 of the second area A2, the absolute value Δn of the difference between the refractive index of the second area A2 and the refractive index of the light transmitting layer LTL, and the light transmittance A2_LT of the second area A2.

The electronic device may include a memory in which a lookup table 710 related to the graphs shown in FIGS. 7A to 7C is stored. Referring to FIG. 7D, the lookup table 710 may include simulation values LT_SV in case that the light control layer LCL has specific parameters. The simulation values LT_SV may be values related to the light transmittance LT for the respective viewing angles VA of the display device DD corresponding to the specific parameters. In an embodiment, the lookup table 710 may include simulation values LT_SV in case that the first height H1 of the first area A1 is about 30 μm, the second height H2 of the second area A2 is about 50 μm, the absolute value Δn of the difference between the refractive index of the second area A2 and the refractive index of the light transmitting layer LTL is about 0.046, and the light transmittance A2_LT of the second area A2 is about 60%. In accordance with the aforementioned embodiment, in case that the viewing angles VA of the light outputted from the display device DD are about 0°, about 30°, and about 45°, the simulation values LT_SV may be about 75.3%, about 39.4%, and about 15.7%, respectively.

Referring to FIGS. 7D to 7F, a processor of the electronic device may determine parameters of the light control layer LCL based on measurement values LT_MV of light outputted from the display device DD and the lookup table 710. The measurement value LT_MV may represent an actually measured value of the light transmittance LT for each viewing angle VA of the light outputted from the display device DD. In accordance with an embodiment, in case that the viewing angles VA of the light outputted from the display device DD are about 0°, about 30°, and about 45°, the measurement values LT_MV may be about 74.3%, about 34.7%, and about 15.2%, respectively. Thus, the processor may generate a measurement table 720 in which the measurement values LT_MV are included. For example, the processor of the electronic device may extract simulation values LT_SV having values similar to the measurement values LT_MV of the measurement table 720. For example, in case that the viewing angles VA is about 0°, about 30°, and about 45°, the simulation values LT_SV extracted by the processor may be about 75.3%, about 39.4%, and about 15.7%, respectively. Thereafter, the processor may determine parameters of the light control layer LCL corresponding to the associated simulation values LT_SV. For example, based on the extracted simulation values LT_SV, the processor may determine that the first height H1 of the light control layer LCL is about 30 μm, the second height H2 is about 50 μm, the absolute value Δn of the difference between the refractive index of the second area A2 and the refractive index of the light transmitting layer LTL is about 0.046, and the light transmittance A2_LT of the second area A2 is about 60%. The electronic device may be implemented as, for example, a computer device including a process and a memory.

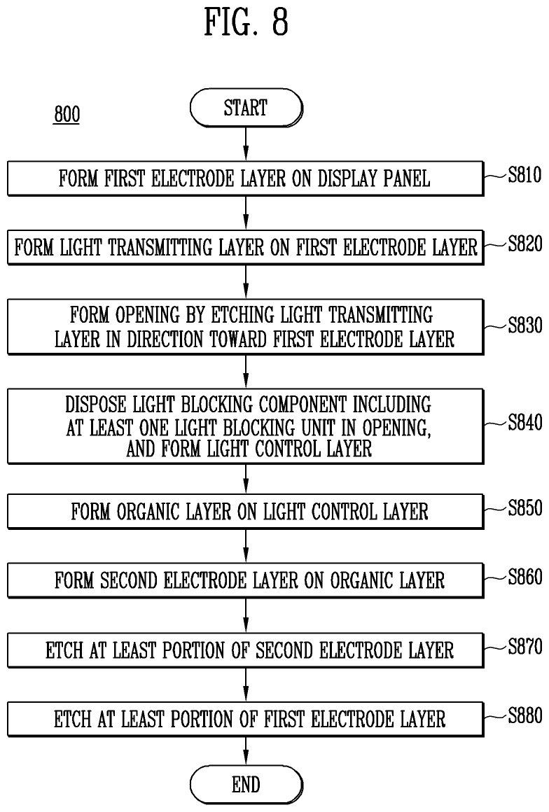

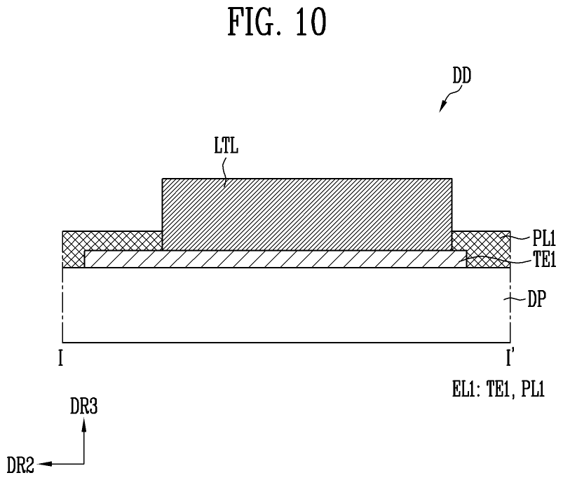

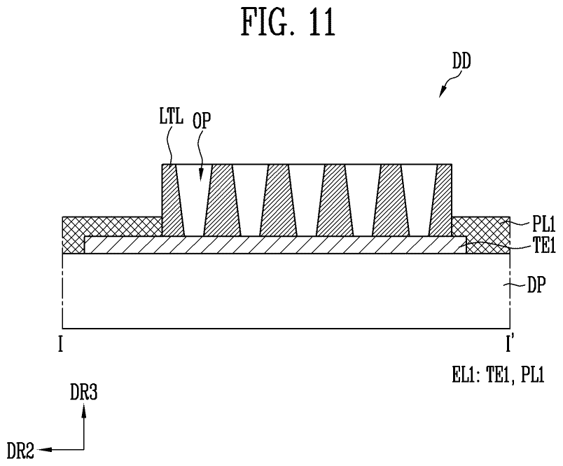

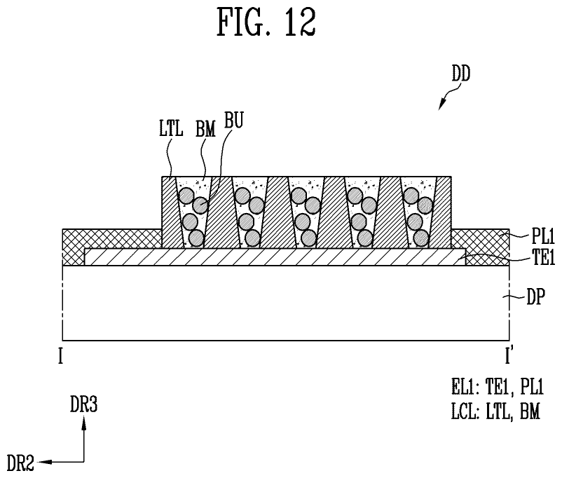

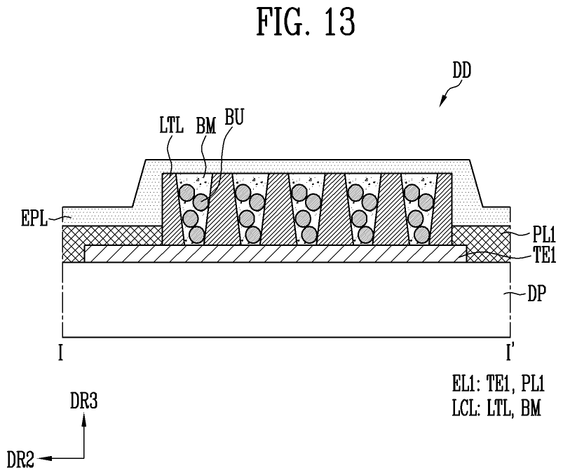

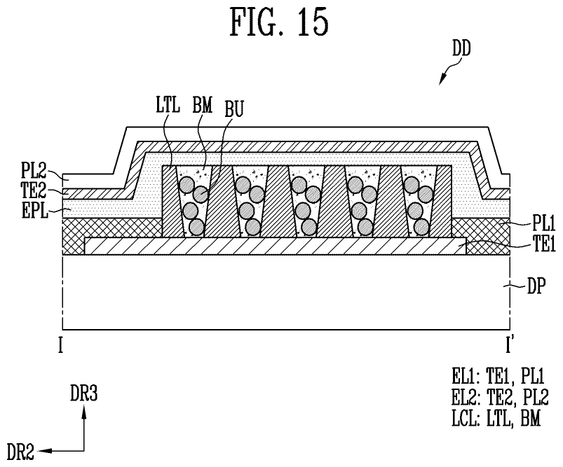

A method of fabricating the display device DD in accordance with an embodiment will be described with reference to FIGS. 8 to 17. Redundant description of the aforementioned contents will be simplified, or may not be repeated for descriptive convenience.

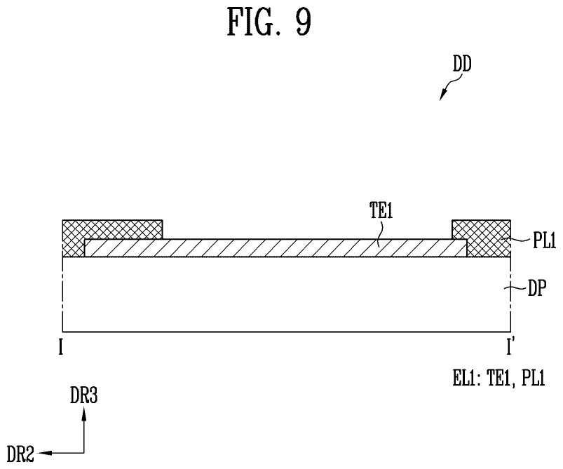

FIG. 8 is a flowchart illustrating a method 800 of fabricating the display device DD in accordance with an embodiment. FIGS. 9 to 17 are schematic sectional views illustrating a method 800 of fabricating the display device DD in accordance with an embodiment.

Referring to FIG. 8, the method 800 of fabricating the display device DD may include a step S810 of forming a first electrode layer EL1 on a display panel DP, a step S820 of forming a light transmitting layer LTL on the first electrode layer EL1, a step S830 of forming an opening by etching the light transmitting layer LTL in a direction toward the first electrode layer EL1, a step S840 of disposing at least one light blocking unit BU in the opening and forming a light control layer LCL, a step S850 of forming an organic layer EPL on the light control layer LCL, and a step S860 of forming a second electrode layer EL2 on the organic layer EPL.

Referring to FIGS. 2, 8, and 9, in the step S810 of forming the first electrode layer EL1 on the display panel DP, a lower electrode TE1 and a first insulating layer PL1 may be formed on the display panel DP.

The lower electrode TE1 may be deposited on the display panel DP. For example, the lower electrode TE1 may be formed on the display panel DP by a sputtering method. However, embodiments are not limited to the aforementioned example.

In an embodiment, the lower electrode TE1 may be formed of any one of indium tin oxide (ITO) and indium zinc oxide (IZO), but embodiments are not limited thereto.

The first insulating layer PL1 may be formed to cover at least a portion of the lower electrode TE1. For example, the first insulating layer PL1 may be formed to cover a first end portion of the lower electrode TE1 and a second end portion thereof extending from the first end portion in the second direction DR2.

The first insulating layer PL1 may include an inorganic material. For example, the first insulating layer PL1 may include one or more of silicon nitride (SiNₓ), silicon oxide (SiOₓ), silicon oxynitride (SiOₓN_{y}), and aluminum oxide (AlₓO_{y}). However, embodiments are not limited to the aforementioned example. For example, the first insulating layer PL1 may include an organic material.

In an embodiment, the first electrode layer EL1 may include a transparent substrate for supporting the lower electrode TE1 and the first insulating layer PL1. For example, the first electrode layer EL1 may further include a transparent substrate including polyethylene terephthalate (PET). Accordingly, the lower electrode TE1 may be formed on the transparent substrate. However, embodiments are not limited thereto. For example, the transparent substrate may not be disposed according to the embodiment.

Referring to FIGS. 2, 8, and 10, in the step S820 of forming the light transmitting layer LTL on the first electrode layer EL1, the light transmitting layer LTL may be formed on the first electrode layer EL1. For example, the light transmitting layer LTL may be formed to overlap the lower electrode TE1. For example, the light transmitting layer LTL may not overlap the first insulating layer PL1 in the third direction DR3. However, embodiments are not limited thereto.

The light transmitting layer LTL may include a transparent organic material. Hence, the light transmitting layer LTL may transmit light outputted from the display panel DP. For example, the light transmitting layer LTL may include transparent resin.

The height of the light transmitting layer LTL may be greater than that of the first electrode layer EL1. For example, the height of the light transmitting layer LTL in the third direction DR3 may be greater than that of the lower electrode TEL and the first insulating layer PL1 in the third direction DR3.

Referring to FIGS. 2, 8, and 11, in the step S830 of forming the opening by etching the light transmitting layer LTL in the direction (e.g., opposite direction to the third direction DR3) toward the first electrode layer EL1, the openings OP may be formed to be spaced apart from each other at regular intervals (or distances). For example, with regard to the light transmitting layer LTL, a photoresist (PR) may remain on some areas of the light transmitting layer LTL through an exposure process and a development processes. Thereafter, areas of the light transmitting layer LTL where the photoresist (PR) is not present (or disposed) may be removed by an etching process to form the openings OP. However, the method of forming the openings OP is not limited to the aforementioned example.

Each of the openings OP may have an inverted trapezoidal shape. However, embodiments are not limited thereto. For example, each of the openings OP may have a forward-trapezoidal shape, a rectangular shape other than the trapezoidal shape, or the like.

The openings OP may expose at least a portion of the lower electrode TE1. For example, the openings OP may expose at least a portion of the lower electrode TE1 in the third direction DR3.

Referring to FIGS. 2, 8, and 12, in the step S840 of disposing the light blocking component including at least one light blocking unit BU in each of the openings and forming the light control layer LCL, the light blocking component BM including the light blocking units BU may be disposed in each of the openings OP, thus forming the light control layer LCL. For example, the light blocking component BM may include the light blocking units BU provided to absorb at least some of the light passing through the light transmitting layer LTL. The light control layer LCL capable of controlling at least some of the light outputted from the display panel DP may be formed by disposing the light blocking component BM in each of the openings OP.

In an embodiment, the light blocking component BM may be disposed in each of the openings OP in a liquid state. For example, the light blocking component BM may be disposed in each of the openings OP in such a way that the light blocking component BM in a liquid state drops into the opening OP. For instance, the light blocking component BM may be disposed in each of the openings OP in such a way that the light blocking component BM in a liquid state is injected into the opening OP. However, embodiments are not limited thereto.

The refractive index of the light blocking component BM and the refractive index of the light transmitting layer LTL may be the same as each other. For example, the refractive index (e.g., absolute refractive index) of the light blocking component BM and the refractive index of the light transmitting layer LTL may be about 1.41. However, embodiments are not limited thereto. Accordingly, total reflection may not occur between the light blocking component BM and the light transmitting layer LTL. For example, light that is incident on a surface of the light blocking component BM may travel (or transmit) into the light blocking component BM rather than being reflected. In accordance with an embodiment, unintended total reflection may not occur between the light blocking component BM and the light transmitting layer LTL.

Referring to FIGS. 2, 8, and 13, in the step S850 of forming the organic layer EPL on the light control layer LCL, an organic layer EPL may be formed to cover at least a portion of the light control layer LCL. In an embodiment, the organic layer EPL may cover at least a portion of the first insulating layer PL1.

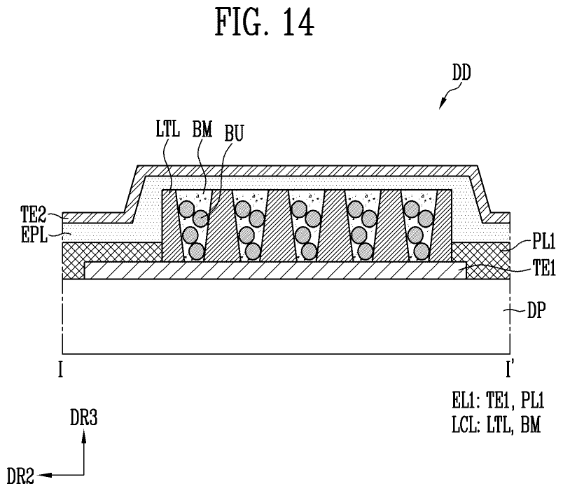

The organic layer EPL may be disposed on the light control layer LCL. The organic layer EPL may cover the light control layer LCL, and have an overall planar surface. For example, the organic layer EPL may function to planarize operations formed on the light control layer LCL. Thus, the upper electrode (TE2, refer to FIG. 14) may be reliably formed on the organic layer EPL.

The organic layer EPL may include an organic material. For example, the organic layer EPL may include an organic material that reacts neither with the light blocking component BM nor with the light blocking units BU.

In the step S850 of forming the organic layer EPL on the light control layer LCL may further include a step of curing the organic layer EPL. Accordingly, the organic layer EPL may reliably cover the light control layer LCL.

In an embodiment, the organic layer EPL may include an acrylic material. According to the corresponding embodiment, the organic layer EPL may be cured by heat.

Furthermore, in another embodiment, the organic layer EPL may include a material such as silicon. According to the corresponding embodiment, the organic layer EPL may be cured by ultraviolet (UV) rays.

Referring to FIGS. 2, 8, 14, and 15, in the step S860 of forming the second electrode layer EL2 on the organic layer EPL, the upper electrode TE2 may be disposed on the organic layer EPL, and the second insulating layer PL2 may be disposed on the upper electrode TE2.

The upper electrode TE2 may be deposited on the organic layer EPL. For example, the upper electrode TE2 may be formed on the organic layer EPL by a sputtering method.

The upper electrode TE2 may be disposed to cover the overall surface of the organic layer EPL. For example, the upper electrode TE2 may be disposed to cover a slant surface of the organic layer EPL.

The upper electrode TE2 may be formed of indium tin oxide (ITO) or indium zinc oxide (IZO), but embodiments are not limited thereto.

The second insulating layer PL2 may be formed to cover the overall surface of the upper electrode TE2. For example, the second insulating layer PL2 may be formed to cover a slant surface of the upper electrode TE2.

The second insulating layer PL2 may include an inorganic material. For example, the second insulating layer PL2 may include one or more of silicon nitride (SiNₓ), silicon oxide (SiOₓ), silicon oxynitride (SiOₓN_{y}), and aluminum oxide (AlₓO_{y}). However, embodiments are not limited to the aforementioned example. For example, the second insulating layer PL2 may include an organic material.

In an embodiment, the second electrode layer EL2 may include a transparent substrate for supporting the upper electrode TE2 and the second insulating layer PL2. For example, the second electrode layer EL2 may further include a transparent substrate including polyethylene terephthalate (PET). Accordingly, the upper electrode TE2 may be formed on the transparent substrate. However, embodiments are not limited thereto. For example, the transparent substrate may not be disposed according to the embodiment.

Referring to FIGS. 8, 16, and 17, the method 800 of fabricating the display device DD in accordance with an embodiment may include a step S870 of etching at least a portion of the second electrode layer EL2, and a step S880 of etching at least a portion of the first electrode layer EL1.

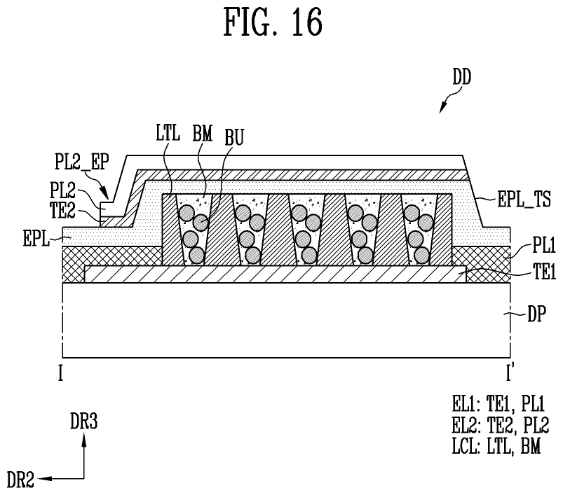

Referring to FIG. 16, in the step S870 of etching at least a portion of the second electrode layer EL2, at least respective portions of the second insulating layer PL2 and the upper electrode TE2 may be etched.

In the step S870, opposite end portions of each of the second insulating layer PL2 and the upper electrode TE2 may be removed so that the organic layer EPL may be exposed. For example, an end portion of each of the second insulating layer PL2 and the upper electrode TE2 with respect to a direction opposite to the second direction DR2 may be etched. Accordingly, a slant surface EPL_TS of the organic layer EPL with respect to the direction opposite to the second direction DR2 may be exposed.

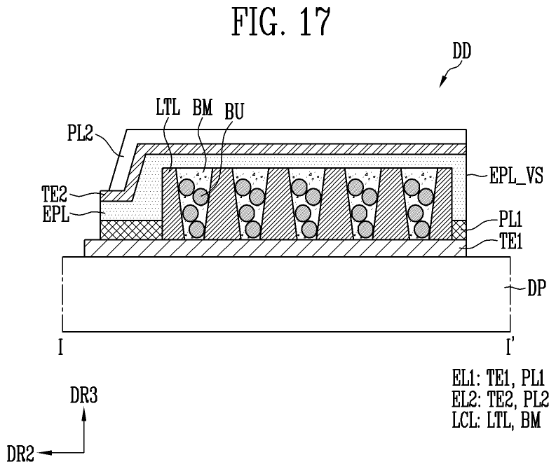

Referring to FIG. 16, the second insulating layer PL2 may include an etched portion PL2_EP that overlaps the upper electrode TE2. For example, a remaining end portion of the second insulating layer PL2 with respect to the second direction DR2 may be the etching portion PL2_EP. For example, referring to FIGS. 16 and 17, in the step S870 of etching at least a portion of the second electrode layer EL2, the etching portion PL2_EP may be removed. Accordingly, at least a portion of the upper electrode TE2 that overlaps the etching portion PL2_EP may be exposed in the third direction DR3, so that the upper electrode TE2 may receive an electrical signal from an external device.

Referring to FIG. 17, in the step S880 of etching at least a portion of the first electrode layer EL1, at least respective portions of the organic layer EPL and the first insulating layer PL1 may be etched. For example, an end portion of each of the organic layer EPL and the first insulating layer PL1 with respect to the second direction DR2 may be etched. Accordingly, at least a portion of the lower electrode TE1 may be exposed in the third direction DR3, so that the lower electrode TE1 may receive an electrical signal from an external device.

Furthermore, the slant surface EPL_TS of the organic layer EPL may be etched. For example, the slant surface EPL_TS of the organic layer EPL may be etched, thereby forming a vertical surface EPL_VS to have a surface substantially parallel to the third direction DR3.

The display device DD in accordance with an embodiment may be fabricated without performing a process of bonding an upper plate and a lower plate. For example, in accordance with the method 800 of fabricating the display device, the first electrode layer EL1, the light control layer LCL, and the second electrode layer EL2 may be sequentially stacked and disposed on the display panel DP.

In accordance with a comparative example, a separate upper surface (e.g., the first electrode layer EL1) and a separate lower surface (e.g., the second electrode layer EL2) may be bonded by a conductive element. Accordingly, an additional bonding process may be needed during the process of fabricating the display device DD.

For example, in accordance with an embodiment, it may be not needed to perform the process of bonding the first electrode layer EL1, the light control layer LCL, and the second electrode layer EL2 by an adhesive, whereby the display device DD may be fabricated by a comparatively simple process.

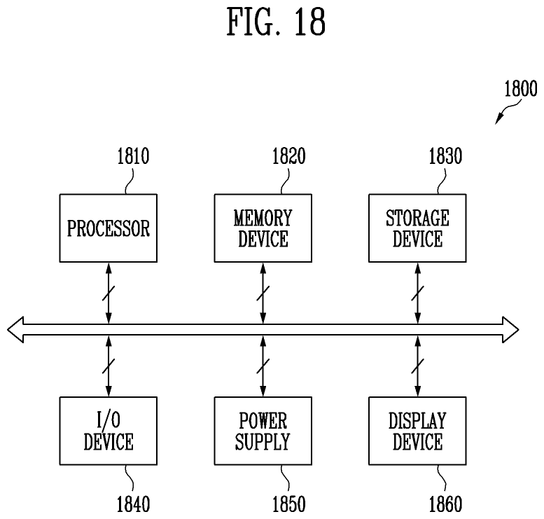

FIG. 18 is a block diagram illustrating an electronic device 1800 in accordance with embodiments.

Referring to FIG. 18, the electronic device 1800 may include a processor 1810, a memory device 1820, a storage device 1830, an input/output (I/O) device 1840, a power supply 1850, and a display device 1860. The display device 1860 may be the display device DD of FIG. 1. The electronic device 1800 may further include various ports for communication with a video card, a sound card, a memory card, a USB device, or other systems. In an embodiment, the electronic device 1800 may be implemented as a navigation system for vehicles. In another embodiment, the electronic device 1800 may be implemented as a smartphone. However, the aforementioned examples are illustrative, and the electronic device 1800 is not limited to the aforementioned examples. For example, the electronic device 1800 may be implemented as a cellular phone, a video phone, a smartpad, a smartwatch, a computer monitor, a laptop computer, a head-mounted display device, or the like.

The processor 1810 may perform specific calculations or tasks. In an embodiment, the processor 1810 may be a microprocessor, a central processing unit, an application processor, or the like. The processor 1810 may be connected to other components through an address bus, a control bus, a data bus, and the like. In an embodiment, the processor 1810 may be connected to an expansion bus such as a peripheral component interconnect (PCI) bus.

The memory device 1820 may store data needed to perform the operation of the electronic device 1800. For example, the memory device 1820 may include non-volatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, and a ferroelectric random access memory (FRAM) device, and/or volatile memory devices such as a dynamic random access memory (DRAM) device, a static random access memory (SRAM) device, a mobile DRAM device, and so on.

The storage device 1830 may include a solid-state drive (SSD), a hard disk drive (HDD), a compact disc read only memory (CD-ROM), or the like.

The I/O device 1840 may include input devices such as a keyboard, a keypad, a touchpad, a touch screen, and a mouse, and output devices such as a speaker and a printer. In an embodiment, the display device 1860 may be included in the I/O device 1840.

The power supply 1850 may supply power needed to perform the operation of the electronic device 1800. For example, the power supply 1850 may be a power management integrated circuit (PMIC).

In an embodiment, power for applying voltages to the first electrode layer (EL1, refer to FIG. 5) and the second electrode layer (EL2, refer to FIG. 5) may be supplied from the power supply 1850. However, embodiments are not limited thereto. For example, the voltages applied to the first electrode layer EL1 and the second electrode layer EL2 may be supplied from a separate power supply (e.g., a battery of a vehicle or the like) provided to supply a voltage to the electronic device 1800.

The display device 1860 may display an image corresponding to visual information of the electronic device 1800. For example, the display device 1860 may be an organic light emitting display device or a quantum dot light emitting display device, but embodiments are not limited thereto. The display device 1860 may be connected to other components through the buses or other communication links.

Various embodiments may provide a display device that outputs an image using a light control layer LCL such that unintended light may be prevented from being visible to a user of the display device DD in a first mode, and the user of the display device may view (or observe) the display device with a relatively wide viewing angle in a second mode.

Various embodiments may provide a method of fabricating the display device DD capable of facilitating a process of fabricating the display device DD including a light control layer LCL.

The effects of the disclosure are not limited by the foregoing, and other various effects are anticipated herein.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel that outputs light for displaying an image;
a first electrode layer disposed on the display panel;
a light control layer including a light blocking component that blocks at least some of the light; and
a second electrode layer disposed on the light control layer, wherein
the light blocking component comprises at least one light blocking unit that is controlled in response to voltages applied to the first electrode layer and the second electrode layer, and
the light blocking unit is substantially uniformly disposed in the light blocking component in a first mode, and is disposed adjacent to any one of the first electrode layer and the second electrode layer in a second mode different from the first mode.

2. The display device of claim 1, wherein
the first electrode layer and the second electrode layer are electrically floated in the first mode, and
voltages of different magnitudes are applied to the first electrode layer and the second electrode layer in the second mode.

3. The display device of claim 1, wherein
voltages having an identical magnitude are applied to the first electrode layer and the second electrode layer in the first mode, and
voltages of different magnitudes are applied to the first electrode layer and the second electrode layer in the second mode.

4. The display device of claim 1, wherein the light blocking component has a trapezoidal shape or an inverted trapezoidal shape.

5. The display device of claim 4, wherein a distance between a first side and a second side of the light blocking component that extend parallel to each other ranges from about 30 μm to about 100 μm.

6. The display device of claim 5, wherein
a length of the second side is about 4 μm or more, and
the length of the second side is less than a length of the first side.

7. The display device of claim 1, wherein
the light blocking component comprises:
a first light blocking component; and
a second light blocking component disposed to be shifted from the first light blocking component by a distance in a range of about 30 μm or more.

8. The display device of claim 1, wherein in the second mode, the light blocking component includes:
a first area in which the light blocking unit is disposed, and
a second area in which the light blocking unit is not disposed.

9. The display device of claim 8, wherein as a vertical length of the first area decreases, a proportion of light passing through the light control layer among the light outputted from the display panel increases.

10. The display device of claim 8, wherein a refractive index of the light control layer is substantially identical to a refractive index of the second area.

11. An electronic device comprising:
a processor that provides input image data to a display device; and
the display device that displays an image based on the input image data, wherein the display device comprises:
a display panel that outputs light for displaying an image;
a first electrode layer disposed on the display panel;
a light control layer including a light blocking component that blocks at least some of the light; and
a second electrode layer disposed on the light control layer,
the light blocking component comprises at least one light blocking unit that is controlled in response to voltages applied to the first electrode layer and the second electrode layer, and
the light blocking unit is substantially uniformly disposed in the light blocking component in a first mode, and is disposed adjacent to any one of the first electrode layer and the second electrode layer in a second mode different from the first mode.

12. A method of fabricating a display device, the method comprising:
forming a first electrode layer on a display panel;
forming a light transmitting layer on the first electrode layer;
forming an opening by etching the light transmitting layer in a direction toward the first electrode layer;
forming a light control layer by disposing a light blocking component including at least one light blocking unit in the opening;
forming an organic layer on the light control layer; and
forming a second electrode layer on the organic layer,
wherein the light blocking unit is controlled according to magnitudes of voltages applied to the first electrode layer and the second electrode layer.

13. The method of claim 12, wherein
the forming of the organic layer comprises curing the organic layer by heat, and
the organic layer includes an acrylic material.

14. The method of claim 12, wherein
the forming of the organic layer comprises curing the organic layer by an ultraviolet ray, and
the organic layer includes a silicon material.

15. The method of claim 12, further including:
etching at least a portion of the second electrode layer;
etching at least a portion of the organic layer; and
etching at least a portion of the first electrode layer.

16. The method of claim 15, wherein
the second electrode layer comprises an upper electrode and an insulating layer disposed to cover at least a portion of the upper electrode,
the insulating layer includes an etching portion overlapping an end portion of the upper electrode, and
the etching of at least the portion of the first electrode layer comprises etching the etching portion.

17. The method of claim 12, wherein, according to the magnitudes of the voltages applied to the first electrode layer and the second electrode layer, the light blocking unit is substantially uniformly disposed in the light blocking component in a first mode and is disposed adjacent to any one of the first electrode layer and the second electrode layer in a second mode different from the first mode.

18. The method of claim 17, wherein
the first electrode layer and the second electrode layer are electrically floated in the first mode, and
voltages of different magnitudes are applied to the first electrode layer and the second electrode layer in the second mode.

19. The method of claim 17, wherein
voltages having an identical magnitude are applied to the first electrode layer and the second electrode layer in the first mode, and
voltages of different magnitudes are applied to the first electrode layer and the second electrode layer in the second mode.

20. The method of claim 19, wherein
the light blocking component has a trapezoidal shape or an inverted trapezoidal shape, and
a distance between a first side and a second side of the light blocking component that extend parallel to each other ranges from about 30 μm to about 100 μm.
